(19) United States
(12) Patent Application Publication
(10) Pub. No.: US 2026/0090383 A1
(43) Pub. Date: Mar. 26, 2026

(54) CHIP THERMAL MANAGEMENT USING COOLANT DELIVERY TO AN EVAPORATIVE CHAMBER

(71) Applicant: Intel Corporation, Santa Clara, CA (US)

(72) Inventors: Je-Young Chang, Tempe, AZ (US); Krishna Vasanth Valavala, Chandler, AZ (US); Rajiv Mongia, Portland, OR (US); Ravindranath Vithal Mahajan, Chandler, AZ (US)

(73) Assignee: Intel Corporation, Santa Clara, CA (US)

(21) Appl. No.: 18/894,618

(22) Filed: Sep. 24, 2024

(51) Int. Cl. H01L 23/473; H01L 21/48; H01L 23/00; H01L 23/367; H01L 23/498; H01L 25/18; H05K 1/18; H10B 80/00

(52) U.S. Cl. CPC H10W 40/47; H10W 40/037; H10W 40/22; H05K 1/181; H10B 80/00; H10W 70/65; H10W 90/00; H10W 90/794

(57) ABSTRACT

Integrated circuit (IC) devices employing thermal management of heat-generating dies.

Heat may be removed from an IC die by supplying a coolant liquid to a chamber thermally coupled to the die and by discharging the coolant from the chamber as a vapor. Measured or provided die and/or coolant parameters may be used to control coolant flow. A device includes a porous structure in a chamber thermally coupled to an IC die, the chamber in a body having a first microchannel network configured for supplying liquid coolant to the chamber and a second microchannel network configured for removing vaporized coolant from the chamber. The chamber may include multiple supply openings for directing or controlling coolant to particular areas of the chamber and one or more associated dies. The chamber may include multiple exhaust openings for removing coolant from particular areas of the chamber.

### BACKGROUND

As integrated circuit (IC) devices are continually scaled down but continually grow more powerful, increasing demands are placed on thermal management of IC dies. Multi-core processing architectures, e.g., with many chips in tighter and tighter spaces, are pushing to higher and higher thermal design powers. These multi-core processors are requiring cooling solutions with greater capabilities, for example, forced liquid cooling solutions, such as microchannel integrated heat spreaders.

While driving coolant liquid through channels adjacent the heat-generating dice has improved heat dissipation capabilities, current solutions will be overcome imminently by yet higher-power processors. The passing of coolant along a series of tightly packed cores generally results in downstream chips (in so-called “thermal shadows”) being inadequately cooled. And liquid cooling has other inherent efficiency limits.

New techniques, structures, and materials are needed to improve the thermal management of high-power IC devices.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile views of an integrated circuit (IC) device having supply and exhaust microchannel networks conveying coolant liquid and vapor, respectively, into and out of a vapor chamber, in accordance with some embodiments;

FIG. 2 illustrates a cross-sectional profile view of an IC system having microchannel networks conveying liquid and vapor coolant into and out of vapor chamber in a silicon body, in accordance with some embodiments;

FIGS. 3A, 3B, 3C and 3D illustrate cross-sectional profile and plan views of IC devices having various microchannel networks conveying coolant between different configurations of inlet and outlet openings of a body and vapor chamber, in accordance with some embodiments;

FIG. 4 is a flow chart of methods for cooling an IC die by supplying coolant to a vapor chamber coupled with the IC die, in accordance with some embodiments;

FIGS. 5A and 5B illustrate cross-sectional profile views of an IC device with dies coupled to a vapor chamber with coolant liquid supplied by and vapor emitted through microchannel networks, in accordance with some embodiments;

FIG. 6 illustrates a diagram of an example data server machine employing an IC device thermally coupled to a two-phase chamber continually supplied with liquid coolant, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to cool high-power integrated circuit (IC) devices.

Integrated heat spreaders (IHS) using microchannels conveying only liquid coolant have inherent heat-capacity limitations, but two-phase solutions may drastically increase capacities by utilizing the latent heat of vaporization. Cooling fluids can dissipate much more thermal energy by absorbing heat and vaporizing. Conventional heat pipes leverage the latent heat of vaporization, but are limited by the amount of coolant within a sealed envelope.

Solutions are disclosed to cool heat-generating IC dies by supplying liquid coolant through a microchannel network to a vapor chamber coupled to the dies and by removing (e.g., exhausting) vaporized coolant from the chamber through another network. The liquid coolant may be pumped into the chamber, and exhausted vapor coolant may be discharged from the chamber to, for example, a condenser where the vapor is cycled back to a liquid. A porous structure in the chamber may promote coolant vaporization by enhancing heat transfer from thermally coupled IC dies into the liquid coolant.

The chamber may have multiple supply openings to enable granular control of the coolant, e.g., to particular areas of the chamber adjacent the most powerful dies or potential hot spots. Coolant control may utilize measurements, e.g., of temperature or electrical power. For example, electrical power supplied to coolant pumps may be correlated to (e.g., increased or decreased with) electrical power supplied to one or more high-power IC dice. Vapor chambers may be any suitable structures and composed of any suitable material(s), including metals (such as copper) or crystalline materials (such as silicon).

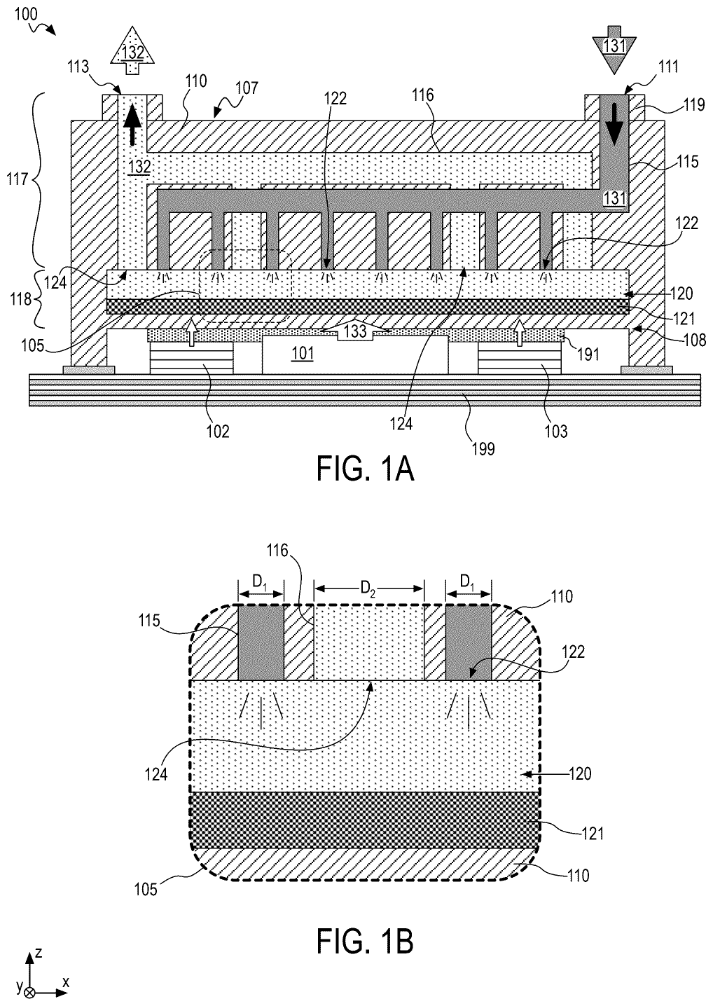

FIGS. 1A and 1B illustrate cross-sectional profile views of an IC device 100 having supply and exhaust microchannel networks 115, 116 conveying coolant liquid 131 and vapor 132, respectively, into and out of a vapor chamber 120, in accordance with some embodiments. FIG. 1A shows IC dies 101, 102, 103 coupled to a body 110 having coolant networks 115, 116 to and from a vapor chamber 120. FIG. 1B illustrates a detailed view 105, magnified from FIG. 1A, of a portion of networks 115, 116 and chamber 120. Note that, for example, for illustrative purposes, some figures may not be strict cross-sectional profiles; some portions of device 100 in separate x-z planes are shown together (e.g., overlapping) in FIG. 1A, etc.

Chamber 120 is thermally coupled to IC dies 101, 102, 103, for example, to draw heat 133 from dies 101, 102, 103. (Heat 133 is represented by one or more arrows, upward from dies 101, 102, 103 in the exemplary embodiment of FIG. 1A.) The transfer of heat 133 (e.g., thermal energy) away from dies 101, 102, 103 may lower a critical junction temperature of dies 101, 102, or 103. To maximize the heat removal from IC dies 101, 102, 103 by chamber 120, chamber 120 is advantageously a two-phase vapor chamber 120. The heat 133 transferred to chamber 120 may increase the temperature of, and vaporize, the coolant in chamber 120, converting liquid 131 to vapor 132. The transfer of the latent heat of vaporization from IC dies 101, 102, 103 to liquid 131 (causing the conversion of liquid 131 to vapor 132) may significantly exceed the thermal energy that would otherwise be shed by dies 101, 102, 103 (e.g., by a conventional, single-phase coolant system).

IC device 100 includes body 110 and chamber 120 in body 110. Body 110 includes upper and lower portions 117, 118 and opposing upper and lower surfaces 107, 108. Lower surface 108 thermally couples chamber 120 and IC die 101. Chamber 120 is internal to body 110, in lower portion 118 of body 110 and adjacent surface 108. A porous structure 121 is in and at the bottom of chamber 120, opposite openings 122, 124 and adjacent surface 108. IC die 101 is under body 110 and coupled to lower portion 118 and lower surface 108, adjacent porous structure 121. IC die 101 is coupled to body 110 at surface 108 by a thermal interface material (TIM) 191.

Supply and exhaust microchannel networks 115, 116 are separate systems of channels through body 110. The channels of networks 115, 116 are referred to as “microchannels” to indicate the small size of the channels of networks 115, 116 (e.g., ˜100 μm across in some embodiments), but networks 115, 116 may both be referred to as “microchannel” networks 115, 116 even when at least some of the channels have diameters of, e.g., 1 mm or more. In many embodiments, microchannels of one of networks 115, 116 have a smallest cross-sectional diameter of less than 1 mm (for example, network 115), microchannels of the other of networks 115, 116 have a smallest cross-sectional diameter of greater than 1 mm (for example, network 116), and both of networks 115, 116 are referred to as microchannel networks 115, 116. Note that the use of the term “diameter” does not imply that a microchannel of networks 115, 116 has a circular profile or exclude other profiles (such as rectangular, etc.) for the microchannels of networks 115, 116. Body 110 may include one or more flanges 119 or other plumbing interfaces with networks 115, 116.

Supply microchannel network 115 is into body 110, in upper portion 117, between chamber 120 and upper surface 107. Supply network 115 is configured to convey liquid 131 to chamber 120. Liquid 131 may be driven into and through network 115 and into body 110 and chamber 120 by a pump or any suitable pressure source. A supply or inlet opening 111 into body 110, in upper portion 117, is coupled by supply network 115 with multiple supply openings 122 at chamber 120. Body 110 may include one or more flanges 119 or other plumbing interfaces to network 115, for example, at opening 111. Liquid 131 may spray or jet into chamber 120 from openings 122.

Liquid 131 (for example, supplied by network 115) may vaporize in chamber 120, e.g., in or on porous structure 121. Advantageously, porous structure 121 provides a high contact area for heat transfer into liquid 131 (e.g., up from IC dies 101, 102, and/or 103, through surface 108, etc.) and for liquid 131 to nucleate and form vapor 132.

Exhaust microchannel network 116 is in upper portion 117, out from chamber 120, between chamber 120 and upper surface 107. Multiple exhaust openings 124 at chamber 120 are coupled by exhaust network 116 with an exhaust or outlet opening 113 out of body 110. Opening 113 is in upper portion 117 and on upper surface 107. Body 110 may include one or more flanges 119 or other plumbing interfaces with network 116, for example, at opening 113. Advantageously, body 110 has both liquid 131 and vapor 132 coolant within chamber 120. Exhaust network 116 is configured to convey vapor 132 (e.g., a liquid-vapor mixture with some vapor quality>0%) from chamber 120. For example, exhaust openings 124 in network 116 may be larger (e.g., have larger diameters or cross-sectional areas) than supply openings 122 in network 115. Exhaust opening 113 in network 116 may be larger than supply opening 111 in network 115. Liquid is likely to be entrained in vapor 132, e.g., as vapor 132 is emitted from chamber 120 and particularly as vapor 132 is further conveyed away from chamber 120 (and the vapor quality likely decreases). The term “vapor” is inclusive of liquid-vapor mixtures. Coolant leaving chamber 120 and referred to as vapor 132 may include liquid-vapor mixtures.

Porous structure 121 advantageously enhances the transfer of heat (e.g., up from IC dies 101, 102, and/or 103) into liquid 131, for example, by providing a structure 121 of thermally beneficial shape and materials. Porous structure 121 preferably provides thermally conductive material(s) in a form having large amounts of heat-transfer surface area but little separation (e.g., thickness or distance) between the coolant in chamber 120 (whether liquid 131 or vapor 132) and the bottom of chamber 120 (and lower surface 108 of body 110). The porosity and the beneficial shapes or forms of structure 121 may allow some of liquid 131 or vapor 132 lower, closer to surface 108, while having thermally conductive structures extending upwards into chamber 120. In the exemplary embodiment of FIG. 1A, porous structure 121 is only along a bottom of chamber 120, but in some embodiments structure 121 spans a height of chamber 120, e.g., as a pillar to provide mechanical support. Porous structure 121 may be similar to wick structures of conventional (e.g., sealed) vapor chambers, but the typical wick function of returning a working fluid back to, e.g., surface 108 is not required (e.g., due to the forced supply of coolant liquid 131).

Porous structure 121 may be made of any appropriate thermally conductive material, including, but not limited to, at least one metal material, alloys of more than one metal, or highly doped glass or highly conductive ceramic material, such as aluminum nitride. In some embodiments, porous structure 121 is or includes a ceramic or metal particles, carbon or metal nanotubes (or other nanostructures), a metallic foam, a sintered metal pad, a metal mesh, and the like, which may further include diamond, copper, nickel, aluminum, alloys thereof, laminated metals including coated materials (such as nickel coated copper), and the like. In the exemplary embodiment of FIG. 1A, porous structure 121 predominantly includes copper particles.

Various thicknesses (e.g., z-heights) and porosities of structure 121 may be employed to best suit the conditions of a particular application (for example, heat flux requirements, coolant viscosities and heat capacities, etc.). Porous structure 121 can be constructed thinner (for example, in the range of 500 μm to 1 mm, to minimize the distance and material between the coolant (e.g., liquid 131) and dies 101, etc.) or thicker (for example, in the range of 2 mm to 3 mm, to meet structural or fabrication requirements). Other thicknesses may be used, e.g., of any suitable dimension(s).

Structure 121 may have any suitable porosity to meet system requirements or to enhance certain capabilities, e.g., heat spreading. As used herein, the term porosity (or void fraction) is defined according to its standard use as the fraction of volume of voids over total volume. In some embodiments, the porosity of structure 121 is 50% (or higher), for example, by deploying particles of uniform size or metal meshes with larger openings. In other embodiments, the porosity is lower (e.g., a fraction less than 35%, such as 25%), for example, by using finer, tighter meshes or by using mixtures of particle sizes (e.g., with smaller particles filling in the voids between larger particles). Other porosity values may be used. In the exemplary embodiment of FIG. 1A, porous structure 121 predominantly includes copper particles having a mixtures of particle sizes and having a minimum porosity of about 15%.

The porosity of structure 121 may be varied with z-height to meet system requirements or to enhance certain capabilities, e.g., heat spreading. In some embodiments, the porosity increases with increasing z-height (into the chamber), such that there is more space for bubbles of vapor 132 as liquid 131 vaporizes on porous structure 121. For example, a portion of porous structure 121 nearer lower surface 108 may have a lower porosity (e.g., a higher density of material and a lower void fraction from a tighter mesh or varied particle sizes) than a portion further from surface 108. In some embodiments, the porosity of a material portion immediately adjacent die 101, etc., and surface 108 is in the range of 15% to 30% and the porosity of a material portion nearer openings 122, 124 is in the range of 40% to 50%. Other porosities may be used. In the exemplary embodiment of FIG. 1A, porous structure 121 predominantly includes copper particles having a mixtures of particle sizes and having a porosity increasing with z-height into chamber 120 to a maximum porosity (e.g., ˜50%) from a minimum porosity (e.g., ˜15%) adjacent lower surface 108.

In some embodiments, some layers or other portions of porous structure 121 include different materials, or have different concentrations of materials, than other layers or other portions. For example, in some embodiments, porous structure 121 has a highest concentration of carbon or copper nanotubes in the portion of structure 121 immediately above die 101, and one or more lower concentrations of carbon or copper nanotubes in one or more other portions of porous structure 121 as the z-height above die 101 increases. Two layers of different concentrations may be one above the other, or other and more gradients of various concentrations can be arranged as suits a particular embodiment.

Body 110 may be any suitable structure and of any suitable material(s). Advantageously, body 110 (generally) and pertinent portions of body 110 have closely matched coefficients of thermal expansion (CTE), e.g., with porous structure 121. At least pertinent portions of body 110 (e.g., lower portion 118 at surface 108) should have sufficient thermal conductance, for example, to maintain a satisfactorily low junction temperature at critical location in dies 101, etc. In many embodiments, body 110 includes copper or another metal. In some such embodiments, body 110 includes the metal (e.g., copper) in a composite, such as a metal-diamond composite body 110. In the exemplary embodiment of FIG. 1A, body 110 is formed predominantly of copper. Advantageously, body has a minimal mismatch of CTE with IC dies 101, 102, 103, as thermal cycles may cause mechanical fatigue of joined materials having significantly disparate CTE. Body 110 is advantageously of a material (or materials) that is mechanically (e.g., structurally) capable of providing an envelope (e.g., of chamber 120) to contain liquid 131 and vapor 132 and of withstanding thermal cycles (e.g., of significant transients of power dissipation) as necessary. Advantageous materials for body 110 are compatible with one or more beneficial coolants (e.g., to be delivered through network 115 as liquid 131 and vaporize into vapor 132 in chamber 120).

Any suitable material(s) may be used as a coolant, and liquid 131 and vapor 132 may be different phases or states of the same coolant material(s). An advantageous coolant material has a high specific heat capacity (e.g., to accept larger amounts of thermal energy from dies 101, 102, or 103), a low boiling point (e.g., to vaporize from liquid 131 into vapor 132 with sufficient margin below a critical junction temperature of dies 101, etc.), a low viscosity (e.g., to facilitate flow through network 115), and other characteristics that aid in the transfer of heat 133 from IC die 101 (etc.) and the maintenance of dies 101, 102, 103 below critical temperatures.

The coolant (e.g., liquid 131) and the material(s) for body 110 (e.g., for chamber 120 and networks 115, 116) may preferentially be chosen for compatibility with each other, e.g., without developing large amounts of non-condensable gas or oxidation products. Material-fluid pairs may be chosen based on temperature operating range. For example, water, methanol, or R134a may be chosen as liquid 131 compatible with a copper body 110. Methanol may be selected for a lower temperature range than water, and R134a (e.g., 1,1,1,2-Tetrafluoroethane) may be chosen for a still lower temperature range. A system pressure may be reduced to lower the boiling point for a chosen coolant liquid 131. For example, a device 100 may operate at a pressure below atmospheric pressure to employ water (which has a beneficially high heat capacity) as liquid 131 with a vaporization or saturation temperature below 100° C. Other liquids 131 may be chosen.

In some embodiments, liquid 131 is a dielectric liquid 131. In some embodiments, liquid 131 is or includes a fluorocarbon-based fluid, such as perfluorocarbons, fluoroketones, hydrofluoroethers, and hydrofluoroolefins. In some embodiments, dielectric liquid 131 includes perfluorohexane. In some embodiments, liquid 131includes a perfluoroalkylmorpholine, such as 2,2,3,3,5,5,6,6-octafluoro-4-(trifluoromethyl)morpholine.

TIM 191 may be employed to couple IC dies 101, 102, 103 and body 110 (e.g., at lower surface 108), for example, in a device 100 with body 110 and die 101 of different materials. For example, TIM 191 may be used to thermally couple die 101 and body 110 in a device 100 with body 110 and die 101 having divergent CTE. TIM 191 may be any appropriate, thermally conductive material, including, but not limited to, a solder, a liquid metal, a mixture of liquid metal and polymer, a thermal grease, a thermal gap pad, a polymer, an epoxy filled with high thermal conductivity fillers, such as metal particles or silicon particles, and the like. Other materials may be utilized.

IC dies 101, 102, 103 are thermally coupled to body 110 by (and chamber 120 through) lower surface 108 and TIM 191. Thermal energy, heat 133, is transferred from heat-sourcing dies 101, etc., to heat-sinking chamber 120. Heat 133 is represented by arrows showing the direction of heat transfer with arrow widths indicating the relative magnitude of heat transfer. In the exemplary embodiment of FIG. 1A, IC die 101 is a processor die, such as a CPU (central processing unit) or GPU (graphics processing unit), and dies 102, 103 are memory dies, which generate and emit less heat 133.

Substrate 199 is a planar platform and may include dielectric and metallization structures. Substrate 199 mechanically supports and electrically couples one or more IC dies (e.g., dies 101, 102, 103, etc.). At least one side of substrate 199 includes substrate interconnect interfaces for bonding to one or more IC dies. Substrate 199 and dies 101, 102, 103, etc., (and body 110) may be bonded by any suitable means, e.g., by solder bumps. The opposite side of substrate 199 may include similar interfaces, e.g., copper pads for socketing and/or solder bumps for bonding other devices 100 or substrates to substrate 199. Substrate 199 may be any host component with substrate interconnect interfaces, for example, a printed circuit board (PCB), such as a motherboard or interposer, another IC die, etc. Substrate 199 may itself be a die. In many embodiments, substrate 199 includes organic dielectric(s), such as a resin or other polymer, between metallization layers. In many embodiments, substrate 199 is a package substrate 199. In many embodiments, one or more of IC dies 101, 102, 103, etc., are coupled to a power supply through substrate 199.

A dotted line in FIG. 1A delineates view 105 of a particular sector of body 110 that is shown magnified in FIG. 1B.

FIG. 1B shows a detailed cross-sectional profile view 105 of body 110 having coolant networks 115, 116 to and from a vapor chamber 120 with a porous structure 121, in accordance with some embodiments. Supply network 115 is configured to convey liquid 131 from inlet opening 111 to openings 122 at chamber 120. As shown, liquid 131 (e.g., delivered by network 115) may spray into chamber 120 from openings 122. Liquid 131 may be directed from openings 122 into chamber 120 and onto porous structure 121. In chamber 120 (e.g., on or in structure 121), liquid 131 may be vaporized, converted into vapor 132 by the transfer of thermal energy from IC dies 101, 102, 103 (equaling or exceeding the latent heat of vaporization of liquid 131), which may maintain dies 101, 102, 103 below their respective critical temperatures.

Exhaust network 116 is configured to convey vapor 132 from openings 124 at chamber 120 to outlet opening 113. Notably, exhaust openings 124 (e.g., to convey coolant in a bulkier state, vapor 132) are larger than supply openings 122. In many embodiments, openings 122 have a first diameter D₁, openings 124 have a second diameter D₂, and second diameter D₂ is greater than first diameter D₁. For example, in many embodiments, openings 122 have diameters D₁ of ˜100 μm or less, and openings 124 have diameters D₂, of ˜1 mm or more. The smaller diameters D₁ of openings 122 (e.g., of ˜100 μm or less) may be well-suited for the supply of liquid 131 to openings 122, while the wider diameters D₂ of openings 124 (e.g., of ˜1 mm or more) may provide less head loss (e.g., resistance to flow and consequent pressure drop through network 116) for the conveyance of bulkier vapor 132.

Again, the term “diameter” in reference to a cross-sectional width does not necessarily indicate that a microchannel has a circular cross-sectional profile. For example, openings 122, 124 of networks 115, 116 and having diameters D₁, D₂, respectively, in FIG. 1B may have other-than-circular cross-sectional profiles, such as rectangular cross-sectional profiles (e.g., substantially rectangular profiles but with rounded corners).

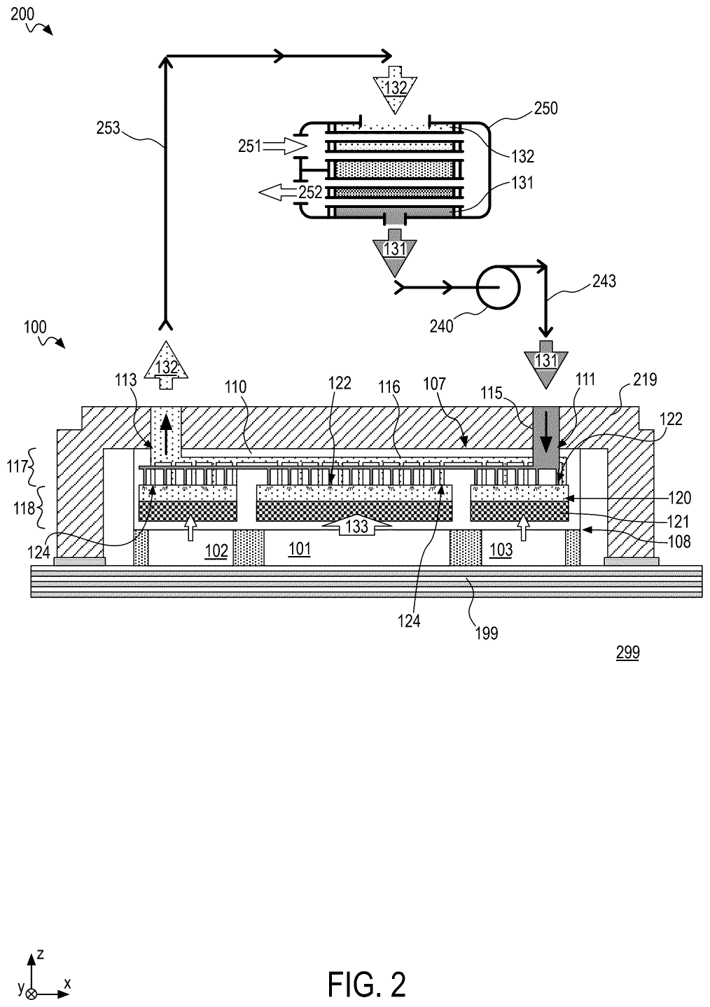

FIG. 2 illustrates cross-sectional profile views of an IC system 200 having microchannel networks 115, 116 conveying liquid 131 and vapor 132 coolant into and out of vapor chamber 120 in a silicon body 110, in accordance with some embodiments. System 200 cools IC dies 101, 102, 103 by the circulation of coolant (e.g., liquid 131 and/or vapor 132) by a pump 240 through a condenser 250 and IC device 100. Notably, silicon body 110 and IC dies 101, 102, 103 are direct bonded and not coupled by any TIM (for example, because body 110 and dies 101, 102, 103 are of the same or similar materials, with close matched CTE).

In the exemplary embodiment of FIG. 2, body 110 is predominantly silicon, porous structure 121 is predominantly silicon, and IC dies 101, 102, 103 are direct bonded to lower surface 108 of body 110, adjacent porous structure 121. In some embodiments, one or more other crystalline materials (e.g., besides pure or nearly pure silicon) are deployed for body 110 (and/or specifically structure 121). Other suitable materials may be used, for example, materials with advantageous thermal conductivities and CTE. The CTE of body 110 (including structure 121) is matched to that of dies 101, 102, 103 (and is low relative to, e.g., copper and most metals), which may improve the reliability of device 100 and system 200 (e.g., by reducing thermally induced fatiguing of CTE-mismatched materials at interfaces of body 110 and dies 101, 102, 103). Other materials (for example, crystalline materials) may have CTE suitably matched to the CTE of dies 101, 102, 103, such as aluminum nitride (and other aluminum compounds, e.g., aluminum oxide), silicon carbide (and other silicon compounds, e.g., silicon nitride), diamond, etc. Different embodiments (e.g., geometries, temperature differences, etc.) may require more closely matched CTE or allow for greater CTE spreads.

The thermal conductivity of silicon, while lower than (e.g.) copper and aluminum, is advantageously higher than that of many metals (e.g., iron and steel, etc.) and of many thermal interface materials (e.g., as described of TIM 191 at FIG. 1A). Furthermore, the use of silicon (or another, e.g., crystalline material with a CTE sufficiently matched to the CTE of dies 101, 102, 103) in body 110 enables direct bonding (e.g., fusion bonding) of body 110 and dies 101, 102, 103, for example, without TIM 191 of FIG. 1A. While more thermally conductive than some other materials, thermal interface materials added between (e.g., in series connection with) body 110 and die 101, etc., can only impeded the transfer of thermal energy (relative to direct-bonded surfaces), and eliminating the need for TIM (even with a body having lower thermal conductivity) may enable higher thermal fluxes from dies 101, etc., to chamber 120. In some embodiments, body 110 and one or more of dies 101, 102, 103 are hybrid bonded (for example, with crystalline materials direct bonded and with direct-bonded metal interfaces, such as bond pads). In some embodiments, one or more crystalline materials (e.g., with high thermal conductivity, with low CTE, and with or without silicon) are utilized in body 110 (e.g., in porous structure 121).

Pump 240 provides the hydraulic pressure to supply coolant liquid 131 to IC device 100 and into chamber 120. Pump 240 may deliver liquid 131 to body 110 by supply line 243 from an outlet of pump 240. Pump 240 may deliver liquid 131 to body 110 and network 115 at inlet opening 111. Any suitable fixture 219 may provide a plumbing interface between supply line 243 and opening 111.

The expansion of liquid 131 to vapor 132 (on top of that from pump 240) may provide sufficient pressure to drive vapor 132 from IC device 100 to condenser 250. Vapor 132 may be conveyed from body 110 by exhaust line 253 to condenser 250. Vapor 132 may be conveyed from body 110 and network 116 at outlet opening 113. Any suitable fixture 219 may provide a plumbing interface between exhaust line 253 and opening 113.

Coolant enters condenser 250 (e.g., at a top of condenser 250) as vapor 132, which is cooled (and reduced in quality) in and by condenser 250. In condenser 250, the heat or enthalpy of condensation is transferred from (e.g., given up by) coolant vapor 132, which condenses into liquid 131. Liquid 131 may be further cooled following condensation. The condensation of vapor 132 into liquid 131 may reduce a pressure in condenser 250 (e.g., to vacuum). The pressure(s) of vapor 132 and/or liquid 131 may be otherwise regulated. Thermal energy transferred from coolant vapor 132 and liquid 131 to a secondary coolant 251, 252 raises a temperature of cold inlet coolant 251 to a temperature of warmed outlet coolant 251. The temperature of warm outlet coolant 251 may be reduced to the temperature of cold inlet coolant 251 by a secondary (e.g., refrigerant) coolant system or any suitable means. Liquid 131 may pool in a collection tank or well at a bottom of or under condenser 250, which may provide sufficient suction head for pump 240.

One or more pumps 240 (e.g., condensate and feed pumps 240) may deliver liquid 131 to one or more IC devices 100. Pump(s) 240 (and other aspects of IC cooling system 200, such as coolant 251 temperature into condenser 250 or pressure in condenser 250) may be controlled using various inputs. IC cooling system 200 may sense, measure, or otherwise input one or more parameters into a control system, for example, that controls the speed (or output pressure) of pump(s) 240 and, consequently, the flow rate of coolant liquid 131 into body 110 and chamber 120. In some embodiments, system 200 senses the pressure, temperature, and/or quality of vapor 132 (e.g., leaving body 110, entering condenser 250, or at some intermediate point along line 253).

Other input parameters may facilitate proactive control of system 200. In many embodiments, system 200 senses (or is provided with) the input power (e.g., voltage and current) supplied to one or more of IC dies 101, 102, 103. In some such embodiments, system 200 uses the input power parameter to control the speed of pump(s) 240. For example, system 200, sensing or being provided that power supplied to a processor die 101 is increasing (or decreasing), may increase (or decrease) the speed of a feed or injection pump 240 supplying liquid 131 to body 110. The use of input power to IC die(s) 101, etc., may advantageously enable improved delivery of coolant liquid 131 to chamber 120, e.g., as demand for coolant and cooling is increasing (rather than after demand has surpassed supply and outlet parameters (e.g., of vapor 132) have reflect insufficient coolant flow and cooling).

Host component 299 is a planar platform and may include dielectric and metallization structures. Host component 299 mechanically supports and electrically couples one or more IC devices 100. At least one side of host component 299 includes substrate interconnect interfaces for bonding to one or more IC devices 100. IC device 100 (and substrate 199) may be bonded by any suitable means to host component 299, e.g., by solder bumps. The opposite side of host component 299 may include similar interfaces, e.g., copper pads for socketing and/or solder bumps for bonding other devices 100 to host component 299. Host component 299 may be any host component with substrate interconnect interfaces, for example, a PCB, such as a motherboard or interposer, another IC die, etc. Host component 299 may itself be a die. In many embodiments, host component 299 includes organic dielectric(s), such as a resin or other polymer, between metallization layers. In many embodiments, host component 299 is a PCB (such as a motherboard), and substrate 199 is a package substrate 199.

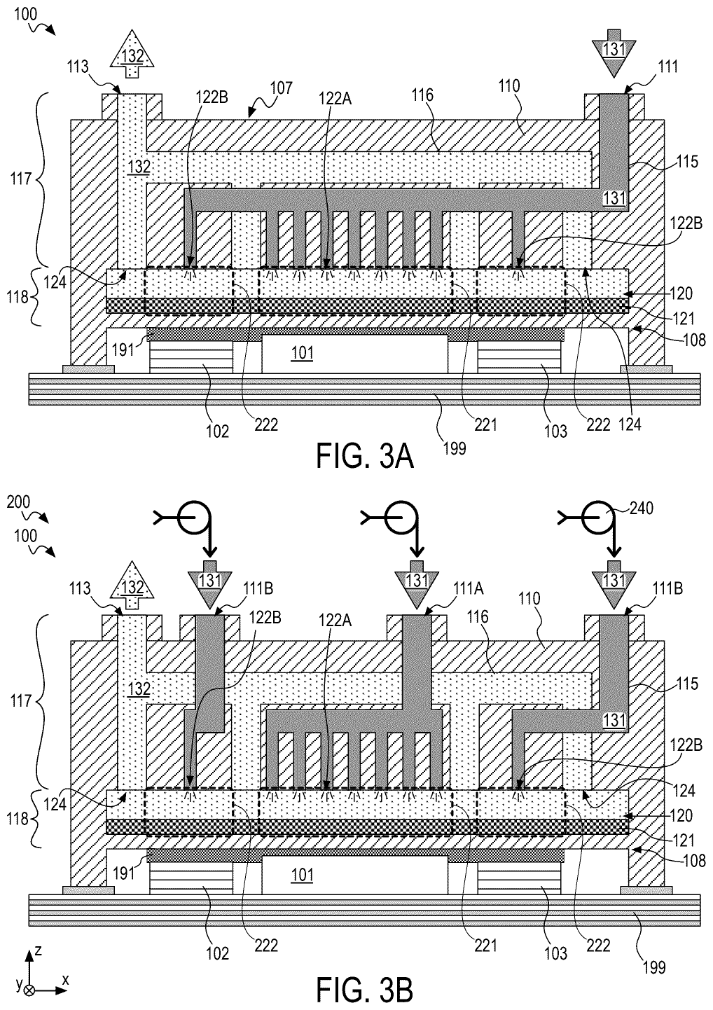

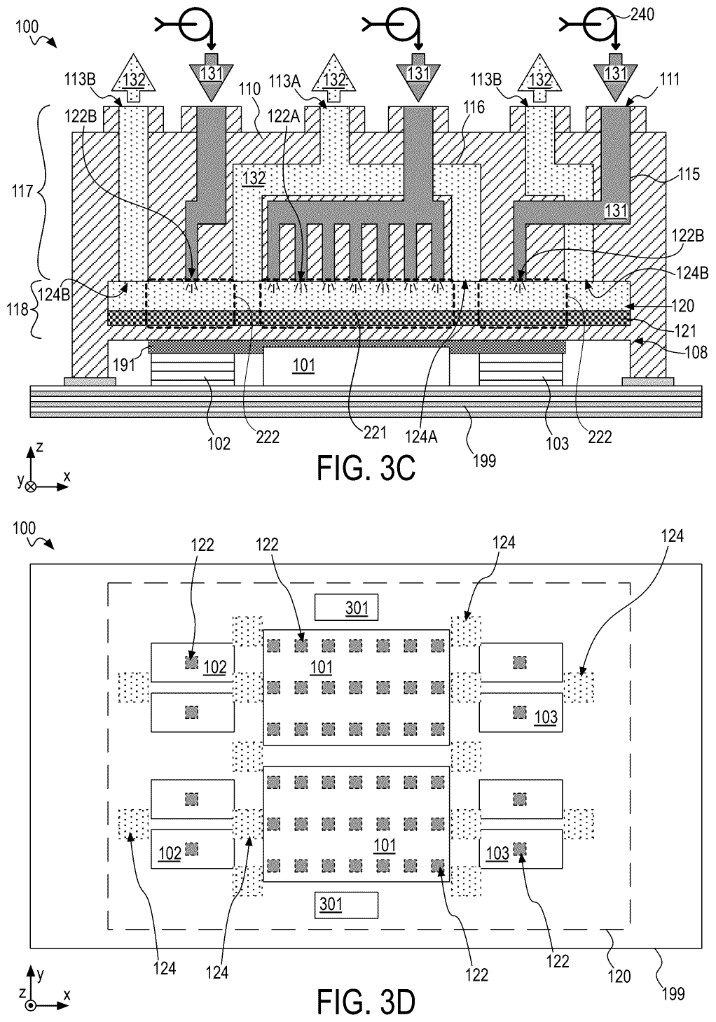

FIGS. 3A, 3B, 3C and 3D illustrate cross-sectional profile and plan views of IC devices 100 having various microchannel networks 115, 116 conveying coolant between different configurations of inlet and outlet openings 111, 113, 122, 124 of body 110 and vapor chamber 120, in accordance with some embodiments. FIG. 3A shows multiple IC dies 101, 102, 103 in device 100 having a supply network 115 with more injection openings 122 to chamber 120 adjacent die 101 than dies 102, 103.

Supply network 115 includes multiple injection openings 122 to chamber 120. Openings 122 to chamber 120 may be distributed to supply more coolant liquid 131 to areas from where more heat is to be dissipated. For example, openings 122 may be distributed more densely in the center of a group of dies or over powerful (e.g., processor) dies rather than low-power (e.g., memory dies). Openings 122 may be distributed with even more granularity, e.g., in higher concentrations over certain expected hot spots of a processor die.

In the exemplary embodiment of FIG. 3A, processor die 101 is coupled to lower surface 108 and lower portion 118 of body 110 adjacent a first sector 221 of chamber 120, and memory dies 102, 103 are each coupled to surface 108 and portion 118 adjacent a corresponding sector 222 of chamber 120. At sector 221 (adjacent processor die 101), a first set of injection openings 122A have a first density (or concentration, e.g., of openings 122A per unit area in an x-y plane or per unit length along an x-axis). At sectors 222 (adjacent either of memory dies 102, 103), each set of injection openings 122B have a second density lower than the first density of openings 122A adjacent processor die 101. In many embodiments, as in the exemplary embodiment of FIG. 3A, openings 122 are distributed with a higher density of openings 122A adjacent a thermally powerful die 101 greater than a lower density of openings 122B adjacent a die 102 or 103 that generates less heat.

FIG. 3B illustrates device 100 having a supply network 115 with dedicated inlet openings 111 for each of dies 101, 102, 103 and corresponding sets of injection openings 122 to chamber 120. An exemplary embodiment of FIG. 3B is similar to an embodiment of FIG. 3A, e.g., having openings 122A, 122B supplying sectors 221, 222 of chamber 120 adjacent IC dies 101, 102, 103. Notably, each of sectors 221, 222 (and their corresponding dies 101, 102, 103) is supplied by a dedicated opening 111A or 111B; the set of openings 122A supplying sector 221 (and die 101) is coupled to opening 111A, and the sets of openings 122B are each coupled to a dedicated opening 111B (and respective die 102 or 103). In some embodiments, a die (e.g., a high-powered die 101) has multiple assigned sectors 221, each with a dedicated opening 111A and set of openings 122A. In some such embodiments, each with a dedicated opening 111A is supplied by a dedicated pump 240.

In some embodiments, as in the exemplary embodiment of FIG. 3B, each sector 221 or 222 (and die 101, 102, or 103) is supplied with coolant liquid 131 by a dedicated pump 240. The dedicated supply (e.g., pump 240) enables the individual control of liquid 131 to each particular IC die 101, 102, or 103, e.g., based on the electrical power delivered (e.g., as sensed by system 200) to that die 101, 102, or 103. For example, pump 240 coupled with openings 122A to sector 221 (adjacent die 101) may increase a supply of coolant liquid 131 to sector 221 (e.g., by increasing a speed of pump 240) based on an increase of power to die 101 (e.g., as processing loads of die 101 are ramped up). This increase of the supply of liquid 131 to sector 221 can be effected without any unnecessary changes to the supplies to sectors 222 and dies 102 and 103, which may each be controlled separately, e.g., based on the electrical power drawn by dies 102 and 103.

FIG. 3C shows device 100 having dedicated inlet openings 111 and outlet openings 113 in supply and exhaust networks 115, 116 for each of dies 101, 102, 103 and corresponding sets of openings 122, 124 at chamber 120. An exemplary embodiment of FIG. 3C is similar to an embodiment of FIG. 3B, e.g., having dedicated pumps 240 and openings 111A, 111B, 122A, 122B supplying sectors 221, 222 adjacent IC dies 101, 102, 103. Notably in FIG. 3C, each of sectors 221, 222 (and their corresponding dies 101, 102, 103) is coupled to a dedicated opening 113A or 113B; the set of openings 124A coupled to sector 221 (and die 101) is coupled to opening 113A, and the sets of openings 124B are each coupled to a dedicated opening 113B (and respective die 102 or 103).

In some embodiments, as in the exemplary embodiment of FIG. 3C, each sector 221 or 222 (and die 101, 102, or 103) exhausts or discharges vapor 132 through a dedicated opening 113A or 113B (in addition to being supplied with coolant liquid 131 by a dedicated pump 240). The dedicated exhaust opening 113A or 113B may support individual control of liquid 131 to each particular IC die 101, 102, or 103, e.g., based on a sensed parameter of vapor 132 (such as pressure, temperature, and/or quality of vapor 132). For example, pump 240 coupled with openings 122A to sector 221 (adjacent die 101) may increase a supply of coolant liquid 131 to sector 221 (e.g., by increasing a speed of pump 240) based on an increase pressure and/or quality of vapor 132 (e.g., as processing loads of die 101 are ramped up and a previous supply of liquid 131 is insufficient for the ramped-up processing load). This increase of the supply of liquid 131 to sector 221 can be effected without any unnecessary changes to the supplies to sectors 222 and dies 102 and 103, which may each be controlled separately, e.g., based on the sensed parameter of vapor 132 discharged from sectors 222 adjacent dies 102 and 103.

FIG. 3D illustrates a plan view of IC device 100 with supply and exhaust openings 122, 124 over multiple processor dies 101 and memory dies 102, 103 on substrate 199. In some embodiments, peripheral dies 301 are not supplied by separate openings 122 or serviced by separate exhaust openings 124. The extent of chamber 120 over dies 101, 102, 103, 301 is delineated by a dashed box. Each of dies 101 is supplied by a higher density of openings 122 (and coupled by adjacent openings 124) than dies 102, 103. Pairs of adjacent dies 102 (or dies 103) may be supplied by a same or separate openings 111B and pumps 240. Pairs of adjacent dies 101 may be supplied by a same or separate openings 111A and pumps 240.

Notably, coolant liquid 131 supplied to chamber 120 adjacent separate dies 101 may advantageously be supplied in parallel, rather than liquid 131 being delivered at a low temperature to (and heated up by) a first die 101 and then at an elevated temperature to a second die 101 (e.g., in a “thermal shadow” of the first die 101). For example, cooled liquid 131 may be supplied to chamber 120 adjacent both dies 101 and vaporized concurrently (e.g., in separate sectors 221), which may ensure that both dies 101 are cooled sufficiently and approximately equally. All IC dies 101, 102, 103, 301 are thermally coupled to the same chamber 120, which may ensure that all dies 101, 102, 103, 301 are maintained around a same, constant temperature (e.g., within an acceptable margin of a saturation temperature of chamber 120).

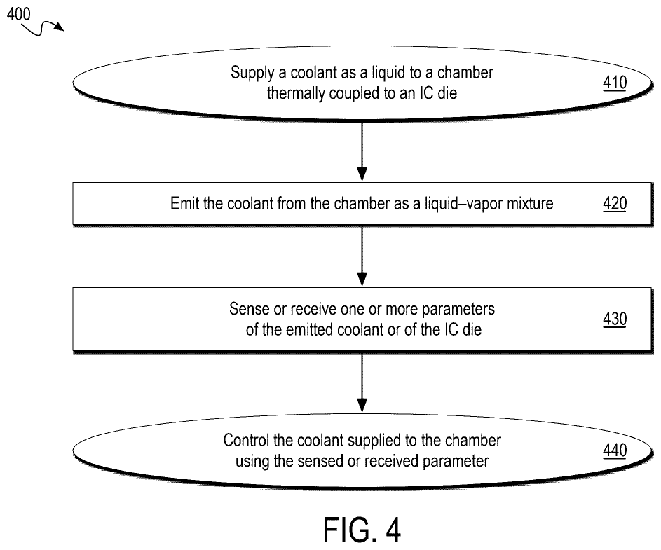

FIG. 4 is a flow chart of methods 400 for cooling an IC die by supplying coolant to a vapor chamber coupled with the IC die, in accordance with some embodiments. Methods 400 include operations 410-440. Some operations shown in FIG. 4 are optional. Additional operations may be included. FIG. 4 shows an example sequence, but the operations can be done in other orders as well, and some operations may be omitted. Some operations can also be performed multiple times before other operations are performed. For example, coolant may be supplied to and emitted (e.g., exhausted) from the chamber without controlling the supply using sensed parameters. Some operations may be included within other operations so that the number of operations illustrated FIG. 4 is not a limitation of the methods 400.

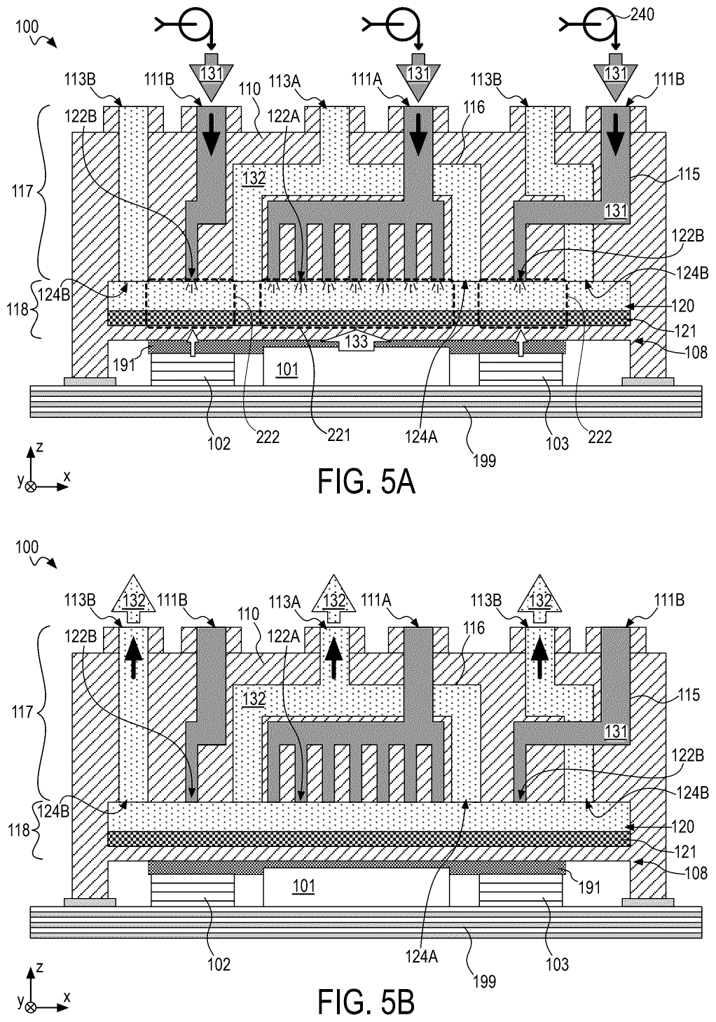

FIGS. 5A and 5B illustrate cross-sectional profile views of IC device 100 with dies 101, 102, 103 coupled to vapor chamber 120 with coolant liquid 131 supplied by and vapor 132 emitted through microchannel networks 115, 116, in accordance with some embodiments. FIGS. 5A and 5B show possible examples of device 100 during an embodiment of a practice of methods 400 of FIG. 4.

Returning to FIG. 4, methods 400 begin at operation 410 with supplying a coolant as a liquid to a chamber thermally coupled to an IC die. The chamber may be a vapor chamber in a two-phase cooling system in which the liquid coolant is vaporized by a latent heat of vaporization transferred to the coolant liquid from one or more IC dies. The transfer of heat from the IC dies may maintain a junction temperature of an IC die below a critical threshold and so prevent damage to the IC die.

In many embodiments, the chamber includes opposing first and second (e.g., upper and lower) sides, one or more supply or injection openings in the first side (e.g., an upper side), and one or more exhaust or discharge openings in the first side. The coolant may be supplied to the chamber by the one or more supply openings in the first side. The IC die is outside the chamber, coupled (e.g., thermally and mechanically) to the chamber adjacent the second side (e.g., a lower side).

The chamber may have any suitable structure and be of any suitable material(s). In many embodiments, the chamber is included in a body, e.g., of a thermally conductive material, such as a metal or crystalline material. The body may have an inlet and a supply microchannel network from the inlet to the supply opening(s) of the chamber. The body may have an outlet and an exhaust microchannel network from the exhaust or discharge opening(s) of the chamber to the outlet. In some embodiments, the body includes multiple inlets and/or multiple outlets.

In many embodiments, the chamber includes a porous structure. The porous structure may promote the transfer of heat from the IC die(s) into the liquid coolant, e.g., up from a lower side of the body and chamber. The porous structure may promote the vaporization of the liquid coolant, for example, by promoting the heat transfer and by providing nucleation sites for the liquid to convert to a vapor. Advantageously, the porous structure is of a thermally conductive material and has a CTE matched to a CTE of other parts of the body. The porous structure may be much as described elsewhere herein (e.g., at least at FIGS. 1A, 1B, and 2).

In many embodiments, the liquid coolant is delivered by the supply network from the inlet(s) to supply openings configured to deliver the liquid to the chamber, for example, by spraying or otherwise injecting the liquid into the chamber and over and onto the porous structure. The supply opening(s) may be of a size optimized for delivering the necessary coolant over the porous structure and chamber thermally coupled to the IC die(s). In some embodiments, microchannel supply openings have a diameter of ˜100 μm or less. The supply network and associated openings may be as described elsewhere herein (e.g., of network 115 and openings 111, 122, at least at FIGS. 1A-3D).

The supply network may include multiple sets of openings, for example, with one or more IC dies thermally coupled to the chamber having a dedicated set of supply openings (e.g., at the chamber) for the delivery of liquid coolant to that IC die. For example, in some embodiments, a first IC die (e.g., a high-powered, processor die) is coupled to the body and chamber adjacent a first area or sector of the chamber, and a second IC die (e.g., a low-powered, memory die) is coupled to the body and chamber adjacent a second area or sector of the chamber. The coolant may be supplied to the first area or sector of the chamber (e.g., adjacent the high-powered, processor die) by a first set of the supply openings, and the coolant may be supplied to the second area or sector of the chamber (e.g., adjacent the low-powered, memory die) by a second set of the supply openings. The first set of supply openings to the area of the chamber adjacent the high-powered, processor die may have a greater concentration of supply openings than the second set of supply openings to the area of the chamber adjacent the low-powered, memory die. The dedicated set of openings allows the coolant supplies to be tailored to areas (and dies) to be cooled, and the tailored supplies may include a larger supply (e.g., with more supply openings at a higher density) for a higher-powered (e.g., processor) die.

In some embodiments, each set of supply openings is coupled to one or multiple inlets of the body dedicated to that set. In some such embodiments, liquid coolant is supplied to each set of supply openings (or at least a particular set of supply openings, e.g., to a high-powered die), through the dedicated one or multiple inlets of the body, by a coolant pump dedicated to that set.

FIG. 5A illustrates IC device 100, in accordance with some embodiments, for example, following a performance of supplying operation 410. Coolant liquid 131 has been delivered by supply pumps 240 to body 110 and supply network 115 at inlet openings 111A, 111B. Coolant liquid 131 has been supplied through microchannel network 115 to supply openings 122A, 122B and vapor chamber 120. Coolant liquid 131 has been injected (e.g., sprayed) from microchannel network 115 into chamber 120 and over porous structure 121. Vaporization heat 133 has been transferred into liquid 131, and vapor 132 has been formed in chamber 120 from liquid 131. The quality of vapor 132 (e.g., the proportion of the liquid-vapor mixture of vapor 132 that is not liquid) may depend on the amount of heat 133 transferred into liquid 131.

Returning to FIG. 4, methods 400 continue with emitting or discharging the coolant from the chamber as a liquid-vapor mixture at operation 420. The coolant may be emitted from the chamber by the one or more exhaust openings in the first (e.g., upper) side. The liquid-vapor coolant may be emitted by the exhaust or discharge microchannel network, from the exhaust opening(s) to the outlet, the exhaust opening(s) configured for the vapor. The exhaust opening(s) may be of a size optimized for conveying the necessary coolant vapor from the chamber, for example, greater than the size (e.g., diameter) of the supply opening(s) for carrying liquid. In some embodiments, microchannel exhaust openings have a diameter of 1 mm or more. The exhaust network and associated openings may be as described elsewhere herein (e.g., of network 116 and openings 113, 124, at least at FIGS. 1A-3D).

The exhaust or discharge network may include multiple sets of openings, for example, with one or more IC dies having a dedicated set of discharge openings (e.g., from the chamber) for the conveyance of vapor coolant from that sector of the chamber and the associated IC die. In some embodiments, each set of exhaust or discharge openings from the chamber is coupled to one or multiple outlets from the body dedicated to that set. In some such embodiments, vapor coolant is conveyed from each set of discharge openings, through the dedicated one or multiple outlets of the body, to a condenser where vapor (such as a liquid-vapor mixture) is converted (i.e., condensed) into liquid coolant. In some embodiments, vapor coolant is conveyed from a particular set of discharge openings (e.g., from a high-powered die), through the dedicated one or multiple outlets of the body to a condenser. Dedicated openings (e.g., at the chamber and the body outlet) for a particular chamber sector and associated IC die(s) enable the sensing of exhaust parameters that may be utilized for coolant control, e.g., of pumped liquid to that sector and die(s).

FIG. 5B shows IC device 100, in accordance with some embodiments, for example, following a performance of emitting operation 420. Coolant vapor 132 formed in vapor chamber 120 from liquid 131 has been discharged through exhaust network 116 from openings 124A, 124B at chamber 120. Coolant vapor 132 has been exhausted by outlet openings 113A, 113B from microchannel network 116 and body 110.

Returning to FIG. 4, methods 400 continue with sensing or receiving a parameter at operation 430, for example, for use in a control system for supplying coolant to the vapor chamber and cooling the IC dies thermally coupled to the chamber. The sensed or received parameter may be used to control the coolant supplied to the chamber, e.g., by providing to the control system information that reflects the effectiveness of (or need for) coolant supplied to the chamber (and to the associated IC dies thermally coupled to the chamber). The parameter may be a sensed (e.g., measured) parameter of the coolant emitted from the chamber or a sensed parameter of the IC die coupled to the chamber. Measured parameters may be sensed by any suitable detectors or sensors, e.g., in any suitable location(s). For example, parameters may be measured in the body (e.g., in or at the chamber), at one or more outlets from the body, at one or more vapor condensers, at an exhaust line between the body and a condenser, at or adjacent an IC die, etc. The parameter may be a received parameter (e.g., received by a control system) of the coolant emitted from the chamber or of the IC die coupled to the chamber. For example, the received parameter may be provided to the system, e.g., a parameter value corresponding to the power to be delivered to the IC die by a power supply, rather than measured or detected by a sensor. In some embodiments, a sensing or supply circuit provides a first electrical power to a coolant pump proportional to a second electrical power provided to one or more IC dies being cooled.

In many embodiments, multiple parameters are sensed or received. In some embodiments, separate parameters (e.g., instances of a same type of measurement or other value) are sensed or received for separate chamber sectors and/or IC dies. For example, a vapor coolant pressure, temperature, and/or quality may be sensed for a first sector or area of the chamber (with a first IC die coupled to the chamber adjacent the first area). The same pressure, temperature, and/or quality measurement may be performed on vapor from a second sector or area of the chamber (with a second IC die coupled adjacent the second area). Parameters measured or sensed from or about a particular sector of the chamber (e.g., from or about a particular outlet from the body or set of discharge openings from the chamber) may be associated with the IC die(s) known to be coupled adjacent that chamber area. In other embodiments, separate parameters may be provided about (for example, directly associated to) the first and second IC dies (e.g., a programmed electrical power to be supplied separately to each of the dies). Parameters measured or provided about individual dies or chamber sectors may advantageously be used to separately control different coolant supplies, e.g., dedicated to particular chamber sectors and associated IC dies.

Returning to FIG. 4, methods 400 continue at operation 440 with controlling coolant supplied to the chamber using a sensed or otherwise provided parameter. The coolant may be controlled by any suitable means. The coolant control may be by a control system on a device to be cooled (such as by one or more of the dies to be cooled) or separate from the cooled device. In many embodiments, a sensed or received parameter is used to control a liquid coolant flow rate. In some such embodiments, the parameter is used to control a coolant pump speed. In some embodiments, the parameter is used to adjust an inlet control valve on a supply line to a body inlet opening. Coolant flow rates may be increased (e.g., by increasing a pump speed or throttling open a control valve) to increase cooling at the chamber of the thermally coupled IC dies.

In some embodiments, a sensed or received parameter is used to control a liquid coolant inlet temperature, for example, by controlling the cooling of the coolant, e.g., at a vapor condenser or by another secondary coolant. The cooling of the coolant may be adjusted by any suitable means, such as increasing a secondary coolant flow rate or temperature. Coolant temperatures may be decreased (e.g., by increasing a secondary coolant flow rate) to increase cooling at the chamber of the thermally coupled IC dies. Other suitable means may be utilized to control coolant supplied to the chamber with a sensed or received parameter.

The coolant control may be done for the entire chamber, for particular chamber sectors and/or IC dies, or a combination of both. In some embodiments, controlling the coolant supplied to the chamber uses a sensed parameter and, e.g., adjusts all of the coolant to the chamber, for example, by increasing (or decreasing) a coolant pump speed to increase (or decrease) the cooling of multiple IC dies coupled to the chamber. In some embodiments, coolant supplied to a first chamber area by one or more corresponding supply openings is controlled using a first parameter associated with the first chamber area (e.g., measured at an exhaust opening from the first chamber area or provided about an IC die coupled adjacent the first chamber area). In some such embodiments, coolant supplied to a second chamber area by one or more corresponding supply openings is controlled using a second parameter associated with the second chamber area (e.g., measured at an exhaust opening from the second chamber area or provided about an IC die coupled adjacent the second chamber area). Coolant supplied to individual chamber areas may be controlled similarly to coolant supplied to the entire chamber, but by separately controlling any dedicated supplies (such as a pump dedicated to a body inlet opening dedicated to a set of injection openings at an individual chamber).

The coolant supply may be controlled reactively and/or proactively. For example, a coolant supply may be reactively controlled by increasing a coolant speed (e.g., pump speed) if an IC die or coolant exhaust measurement exhibits a need for more cooling. An IC die temperature measurement increasing excessively may reactively trigger an increase of cooling. A proactive control may increase a coolant pump speed whenever electrical power supplied to an IC die (or, e.g., to be supplied, for example, by a programmed or planned increase of power to the IC die) is sensed by or otherwise provided to the control system.

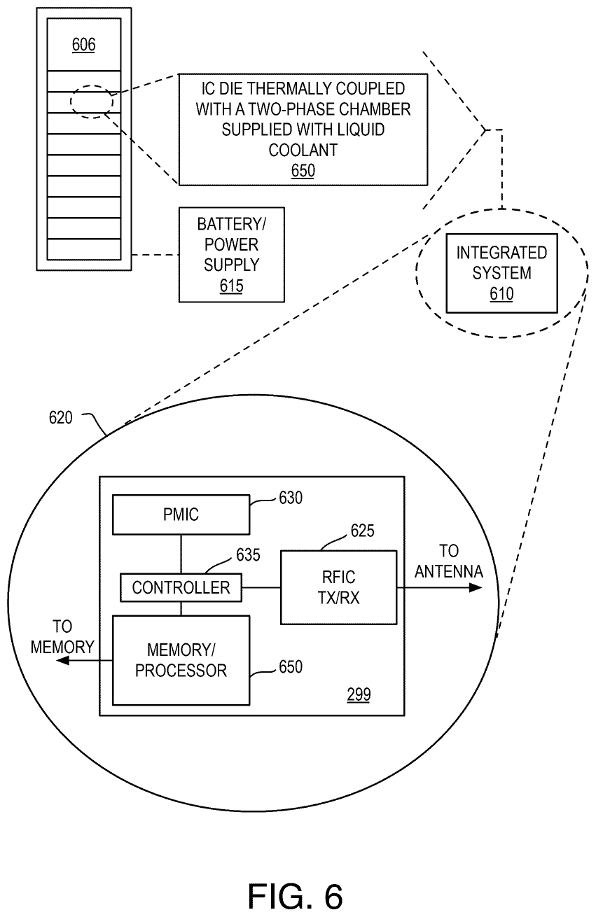

FIG. 6 illustrates a diagram of an example data server machine 606 employing an IC device thermally coupled to a two-phase chamber continually supplied with liquid coolant, in accordance with some embodiments. Server machine 606 may be any commercial server, for example, including any number of high-performance computing platforms disposed within a rack and networked together for electronic data processing, which in the exemplary embodiment includes one or more devices 650 thermally coupled to a two-phase chamber continually supplied with liquid coolant.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device thermally coupled to a two-phase chamber continually supplied with liquid coolant, as discussed herein. Device 650 may be further coupled to (e.g., communicatively coupled to) a board, an interposer, or a host component 299 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 include thermally coupled to a two-phase chamber continually supplied with liquid coolant.

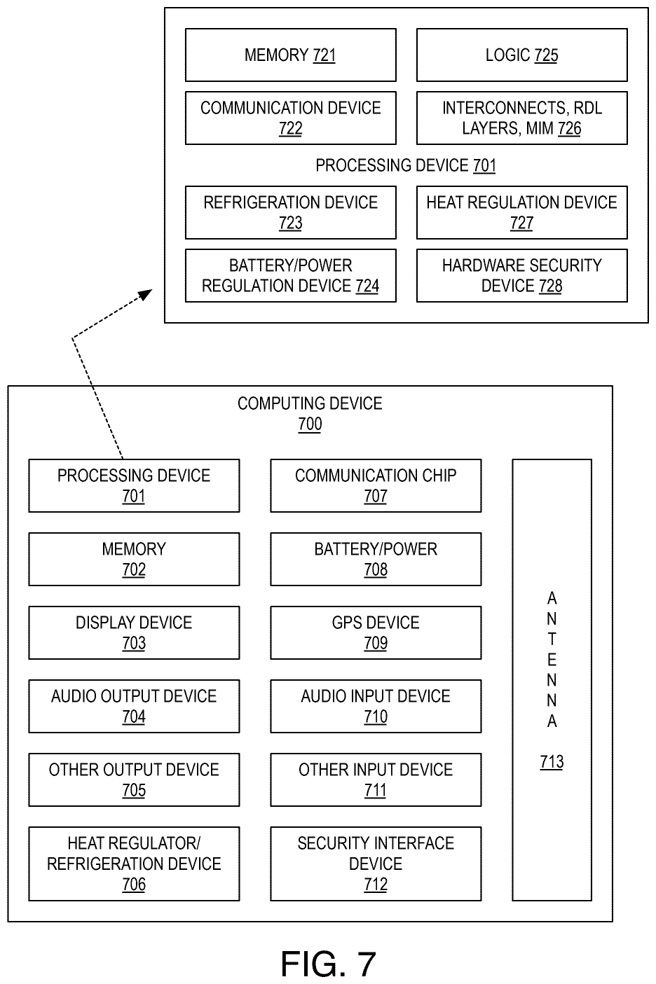

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a chamber in a body including opposing first and second surfaces, the first surface to thermally couple the chamber and an IC die, wherein the chamber is adjacent the first surface, and a porous structure is in the chamber and adjacent the first surface, one or more first openings into the body, coupled with one or more second openings at the chamber by a first microchannel network in the body and between the chamber and the second surface, the first microchannel network configured to convey a liquid from the one or more first openings to the one or more second openings, and at least a third opening out of the body, coupled with one or more fourth openings at the chamber by a second microchannel network in the body and between the chamber and the second surface, the second microchannel network configured to convey a liquid-vapor mixture from the one or more fourth openings to at least the third opening.

In one or more second embodiments, further to the first embodiments, the IC die is coupled to the first surface of the body, adjacent the porous structure.

In one or more third embodiments, further to the first or second embodiments, a first of the one or more second openings has a first diameter, a first of the one or more fourth openings has a second diameter, and the second diameter is greater than the first diameter.

In one or more fourth embodiments, further to the first through third embodiments, the first microchannel network couples with a plurality of second openings at the chamber.

In one or more fifth embodiments, further to the first through fourth embodiments, the plurality of second openings includes a first set of second openings with a first density at a first sector of the chamber, the plurality of second openings includes a second set of second openings with a second density at a second sector of the chamber, and the first density is greater than the second density.

In one or more sixth embodiments, further to the first through fifth embodiments, the first set of second openings is coupled to a first of the first openings, and the second set of second openings is coupled to a second of the first openings.

In one or more seventh embodiments, further to the first through sixth embodiments, a first IC die is coupled to the first surface of the body, adjacent the first sector of the chamber, and a second IC die is coupled to the first surface of the body, adjacent the second sector of the chamber.

In one or more eighth embodiments, further to the first through seventh embodiments, the second microchannel network couples the third opening on the second surface with a plurality of fourth openings at the chamber.

In one or more ninth embodiments, further to the first through eighth embodiments, the body includes silicon, the porous structure includes silicon, and an IC die is direct bonded to the first surface of the body, adjacent the porous structure.

In one or more tenth embodiments, an apparatus includes a chamber in a body including upper and lower portions, the chamber in the lower portion, an IC die coupled to the lower portion of the body, a first microchannel network into the body, in the upper portion, the first microchannel network coupling one or more first openings in the upper portion and a plurality of second openings at the chamber, and a second microchannel network out from the chamber, in the upper portion, the second microchannel network coupling one or more third openings in the upper portion and a plurality of fourth openings at the chamber.

In one or more eleventh embodiments, further to the tenth embodiments, a porous structure is in the chamber, opposite the second and fourth openings.

In one or more twelfth embodiments, further to the tenth or eleventh embodiments, a first of the second openings has a first diameter, a first of the fourth openings has a second diameter, and the second diameter is greater than the first diameter.

In one or more thirteenth embodiments, further to the tenth through twelfth embodiments, the plurality of second openings includes a first set of second openings with a first density at a first sector of the chamber, the plurality of second openings includes a second set of second openings with a second density at a second sector of the chamber, and the first density is greater than the second density.

In one or more fourteenth embodiments, further to the tenth through thirteenth embodiments, the first set of second openings is coupled to a first of the one or more first openings, and the second set of second openings is coupled to a second of the one or more first openings.

In one or more fifteenth embodiments, further to the tenth through fourteenth embodiments, a first IC die is coupled to the lower portion of the body, adjacent the first sector of the chamber, and a second IC die is coupled to the lower portion of the body, adjacent the second sector of the chamber.

In one or more sixteenth embodiments, a method includes supplying a coolant as a liquid to a chamber thermally coupled to an IC die, wherein the chamber includes opposing first and second sides, one or more first openings in the first side, and one or more second openings in the first side, the coolant is supplied to the chamber by the one or more first openings in the first side, and the IC die is outside the chamber, coupled to the chamber adjacent the second side, and emitting the coolant from the chamber as a liquid-vapor mixture, wherein the coolant is emitted from the chamber by the one or more second openings in the first side.

In one or more seventeenth embodiments, further to the sixteenth embodiments, the method also includes sensing or receiving a parameter of the coolant emitted from the chamber or of the IC die coupled to the chamber, wherein the parameter is used to control the coolant supplied to the chamber.

In one or more eighteenth embodiments, further to the sixteenth or seventeenth embodiments, a body includes the chamber, an inlet, and an outlet, the coolant is supplied as the liquid by a first microchannel network from the inlet to the one or more first openings, a first of the one or more first openings having a first diameter, the coolant is emitted as the liquid-vapor mixture by a second microchannel network from the one or more second openings to the outlet, a first of the one or more second openings having a second diameter, and the second diameter is greater than the first diameter.

In one or more nineteenth embodiments, further to the sixteenth through eighteenth embodiments, the IC die is a first IC die, coupled to the chamber adjacent a first area, a second IC die is coupled to the chamber adjacent a second area, a first parameter of the first IC die is sensed or received, a second parameter of the second IC die is sensed or received, the coolant is supplied to the first area of the chamber by at least a first of the first openings, the coolant is supplied to the second area of the chamber by at least a second of the first openings, the first parameter is used to control the coolant supplied to the first area by the first of the first openings, and the second parameter is used to control the coolant supplied to the second area by the second of the first openings.

In one or more twentieth embodiments, further to the sixteenth through nineteenth embodiments, the IC die is a first IC die, coupled to the chamber adjacent a first area, a second IC die is coupled to the chamber adjacent a second area, the coolant is supplied to the first area of the chamber by a first plurality of the first openings, the coolant is supplied to the second area of the chamber by a second plurality of the first openings, and the first plurality of the first openings has a greater concentration of the first openings than the second plurality of the first openings.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a chamber in a body comprising opposing first and second surfaces, the first surface to thermally couple the chamber and an integrated circuit (IC) die, wherein the chamber is adjacent the first surface, and a porous structure is in the chamber and adjacent the first surface;
one or more first openings into the body, coupled with one or more second openings at the chamber by a first microchannel network in the body and between the chamber and the second surface, the first microchannel network configured to convey a liquid from the one or more first openings to the one or more second openings; and
at least a third opening out of the body, coupled with one or more fourth openings at the chamber by a second microchannel network in the body and between the chamber and the second surface, the second microchannel network configured to convey a liquid-vapor mixture from the one or more fourth openings to at least the third opening.

2. The apparatus of claim 1, wherein the IC die is coupled to the first surface of the body, adjacent the porous structure.

3. The apparatus of claim 1, wherein:
a first of the one or more second openings has a first diameter;
a first of the one or more fourth openings has a second diameter; and
the second diameter is greater than the first diameter.

4. The apparatus of claim 1, wherein the first microchannel network couples with a plurality of second openings at the chamber.

5. The apparatus of claim 4, wherein:
the plurality of second openings comprises a first set of second openings with a first density at a first sector of the chamber;
the plurality of second openings comprises a second set of second openings with a second density at a second sector of the chamber; and
the first density is greater than the second density.

6. The apparatus of claim 5, wherein:
the first set of second openings is coupled to a first of the first openings; and
the second set of second openings is coupled to a second of the first openings.

7. The apparatus of claim 5, wherein:
a first IC die is coupled to the first surface of the body, adjacent the first sector of the chamber; and
a second IC die is coupled to the first surface of the body, adjacent the second sector of the chamber.

8. The apparatus of claim 1, wherein the second microchannel network couples the third opening on the second surface with a plurality of fourth openings at the chamber.

9. The apparatus of claim 1, wherein:
the body comprises silicon;
the porous structure comprises silicon; and
an IC die is direct bonded to the first surface of the body, adjacent the porous structure.

10. An apparatus, comprising:
a chamber in a body comprising upper and lower portions, the chamber in the lower portion;
an integrated circuit (IC) die coupled to the lower portion of the body;
a first microchannel network into the body, in the upper portion, the first microchannel network coupling one or more first openings in the upper portion and a plurality of second openings at the chamber; and
a second microchannel network out from the chamber, in the upper portion, the second microchannel network coupling one or more third openings in the upper portion and a plurality of fourth openings at the chamber.

11. The apparatus of claim 10, wherein a porous structure is in the chamber, opposite the second and fourth openings.

12. The apparatus of claim 11, wherein:
a first of the second openings has a first diameter;
a first of the fourth openings has a second diameter; and
the second diameter is greater than the first diameter.

13. The apparatus of claim 12, wherein:
the plurality of second openings comprises a first set of second openings with a first density at a first sector of the chamber;
the plurality of second openings comprises a second set of second openings with a second density at a second sector of the chamber; and
the first density is greater than the second density.

14. The apparatus of claim 13, wherein:
the first set of second openings is coupled to a first of the one or more first openings; and
the second set of second openings is coupled to a second of the one or more first openings.

15. The apparatus of claim 13, wherein:
a first IC die is coupled to the lower portion of the body, adjacent the first sector of the chamber; and
a second IC die is coupled to the lower portion of the body, adjacent the second sector of the chamber.

16. A method, comprising:
supplying a coolant as a liquid to a chamber thermally coupled to an integrated circuit (IC) die, wherein:
the chamber comprises opposing first and second sides, one or more first openings in the first side, and one or more second openings in the first side;
the coolant is supplied to the chamber by the one or more first openings in the first side; and
the IC die is outside the chamber, coupled to the chamber adjacent the second side; and
emitting the coolant from the chamber as a liquid-vapor mixture, wherein the coolant is emitted from the chamber by the one or more second openings in the first side.

17. The method of claim 16, further comprising sensing or receiving a parameter of the coolant emitted from the chamber or of the IC die coupled to the chamber, wherein the parameter is used to control the coolant supplied to the chamber.

18. The method of claim 16, wherein:
a body comprises the chamber, an inlet, and an outlet;
the coolant is supplied as the liquid by a first microchannel network from the inlet to the one or more first openings, a first of the one or more first openings having a first diameter;
the coolant is emitted as the liquid-vapor mixture by a second microchannel network from the one or more second openings to the outlet, a first of the one or more second openings having a second diameter; and
the second diameter is greater than the first diameter.

19. The method of claim 16, wherein:
the IC die is a first IC die, coupled to the chamber adjacent a first area;
a second IC die is coupled to the chamber adjacent a second area;
a first parameter of the first IC die is sensed or received;
a second parameter of the second IC die is sensed or received;
the coolant is supplied to the first area of the chamber by at least a first of the first openings;
the coolant is supplied to the second area of the chamber by at least a second of the first openings;
the first parameter is used to control the coolant supplied to the first area by the first of the first openings; and
the second parameter is used to control the coolant supplied to the second area by the second of the first openings.

20. The method of claim 16, wherein:
the IC die is a first IC die, coupled to the chamber adjacent a first area;
a second IC die is coupled to the chamber adjacent a second area;
the coolant is supplied to the first area of the chamber by a first plurality of the first openings;
the coolant is supplied to the second area of the chamber by a second plurality of the first openings; and
the first plurality of the first openings has a greater concentration of the first openings than the second plurality of the first openings.
